(19) United States
(12) Patent Application Publication
(10) Pub. No.: US 2022/0310861 A1
(43) Pub. Date: Sep. 29, 2022

(54) COLOR-MODIFIED LUMINESCENT CONCENTRATOR

(71) Applicant: UbiQD, Inc., Los Alamos, NM (US)

(72) Inventors: AARON JACKSON, Los Alamos, NM (US); MATTHEW BERGREN, Los Alamos, NM (US); HUNTER MCDANIEL, Los Alamos, NM (US)

(21) Appl. No.: 17/618,346

(22) PCT Filed: Jun. 10, 2020
(86) PCT No.: PCT/US20/37093

§ 371 Date: Dec. 10, 2021

Related U.S. Application Data
(60) Provisional application No. 62/859,630, filed on Jun. 10, 2019.

(51) Int. Cl. H01L 31/055; E06B 9/24; C09K 11/08; C09K 11/58; C09K 11/62; H01L 31/054; G02B 5/20; G02B 1/04

(52) U.S. Cl. CPC H01L 31/055; E06B 9/24; C09K 11/0811; C09K 11/582; C09K 11/621; H01L 31/0547; G02B 5/206; G02B 1/04; E06B 2009/2476; B82Y 20/00

(57) ABSTRACT

A laminated glass luminescent concentrator is provided which includes a solid medium having a plurality of fluorophores disposed therein. In some embodiments, the fluorophore is a low-toxicity quantum dot. In some embodiments, the fluorophore has significantly reduced self-absorption, which allows for unperturbed waveguiding of the photoluminescence over a long distance. Also disclosed are apparatuses for generating electricity from the laminated glass luminescent concentrator, and its combination with buildings and vehicles.

### CROSS-REFERENCE TO RELATED APPLICATIONS

This application is a national stage filing of PCT/US20/37093, filed on Jun. 10, 2020, having the same inventors and the same title, and which is incorporated herein by referenced in its entirety; which claims the benefit of priority from U.S. Provisional Application No. 62/859,630 filed Jun. 10, 2019, having the same inventors, and the same title, and which is incorporated herein by reference in its entirety.

### ACKNOWLEDGMENT OF GOVERNMENT SUPPORT

This invention was made with Government support under Contract No. 1622211 awarded by the National Science Foundation. The Government has certain rights to this invention.

### FIELD OF THE DISCLOSURE

The present disclosure relates generally to color-modified devices, preferably with a neutral grey color, featuring photoluminescent materials embedded within a waveguide, and more specifically to luminescent concentrators containing photoluminescent materials (such as quantum dots) in combination with a colorant, and to systems utilizing the same in conjunction with a photovoltaic cell for the generation of electricity.

### BACKGROUND OF THE DISCLOSURE

Luminescent concentrators (LCs) are devices which utilize luminescent materials to harvest electromagnetic radiation, typically for the purpose of generating electricity. FIG. 1 depicts a common set-up for such a device 101. As seen therein, the LC 102 is utilized as a waveguide which collects solar radiation 103 over a relatively large area, and concentrates it onto a relatively small area (here, the active surface of a photovoltaic cell 104). The photovoltaic cell 104 then converts the radiation into electricity to provide power 105 for end use devices 106.

The waveguide portion of the LC 102 typically comprises a luminescent material disposed in a polymeric medium. The polymeric medium is typically of optical quality, and contains a suitable color pigment. In order to be an effective component of the waveguide, the luminescent material must be highly transmissive over its primary emission wavelengths.

When sunlight or other radiation impinges on the luminescent material, the material undergoes luminescence (and most commonly, fluorescence) and emits light into the waveguide. From there, the entrapped light is directed to the photovoltaic cell 104. Since the radiation emitted by the luminescent material is typically emitted at different wavelengths than the radiation initially absorbed by the luminescent material, the luminescent LC 102 has the effect of both concentrating and modifying the spectrum of the radiation which is impingent on it.

One of the first reports of an LC can be found in U.S. Pat. No. 4,227,939 (Zewail et al), entitled “Luminescent Solar Energy Concentrator Devices,” which was filed in 1979. This reference notes that “Snell's law dictates that a large fraction, typically 75%, of this reemission strikes the surface of the substrate with an angle of incidence greater than the critical angle, so that this fraction of the light is then trapped in the substrate by internal reflection until successive reflection carries it to the edge of the plate where it enters an absorber placed at the edge of the plate.” One of the biggest drawbacks of this approach is its reliance on a monolithic polymer slab/sheet as a structural material for a window, building, or vehicle, since polymeric materials are frequently not reliable in outdoor conditions. Moreover, the typical polymeric materials that are useful in this application are prone to abrasion. In addition to perturbing the view through a window, abrasion also impairs LC performance by introducing light scattering centers into the waveguide.

### BRIEF DESCRIPTION OF THE DRAWINGS

FIG. 1 is a schematic illustration of an LC wherein a fluorophore and colorant are embedded in a polymer medium. The concentrator is coupled to a photovoltaic cell for the conversion of light into electricity.

FIG. 2 is a typical spectrum for windows containing the QDs and colorant. Curve 1 (dashed line) depicts the spectrum of a window containing only quantum dots, while Curve 2 (solid line) depicts the window containing quantum dots and a Victoria blue colorant.

FIG. 3 is a schematic illustration of a product having a first film containing QDs embedded in a polymer matrix, and a second film containing a blue colorant which is coated or adhered to a surface of a window unit (not shown).

FIG. 4 is a schematic illustration of a product having QDs incorporated into a polymer matrix that is used as an interlayer or coating on a glass substrate. The colorant is incorporated into a separate polymer matrix that is used as an interlayer or coating on one or more separate glass substrates.

FIG. 5 is an image showing three different tints with different concentrations of QDs and colorant. The left sample depicts 2w % QDs without colorant, the center sample depicts 2w % QDs with colorant, and the right depicts 4w % QDs with colorant.

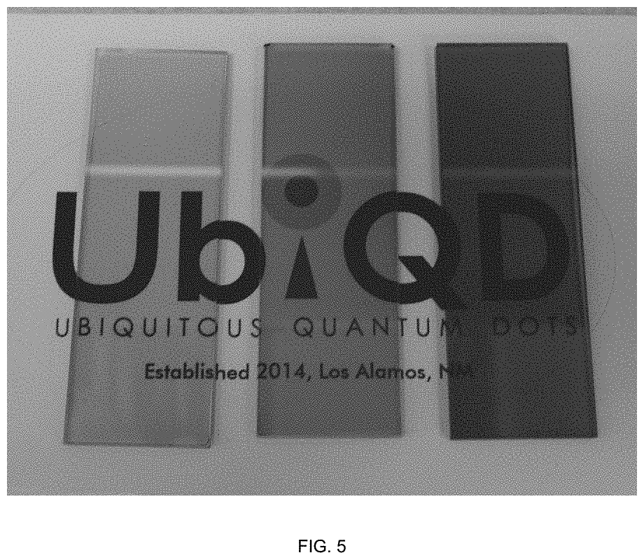

FIG. 6 shows QDs in a glass laminate in an IGU with a low-e coating on a separate glass substrate from the LC. The separate blue and QD laminates are depicted, in which the left image is QD only, the center image is QD+colorant in one laminate, and the right image features a QD laminate on the bottom, and a colorant laminate on top.

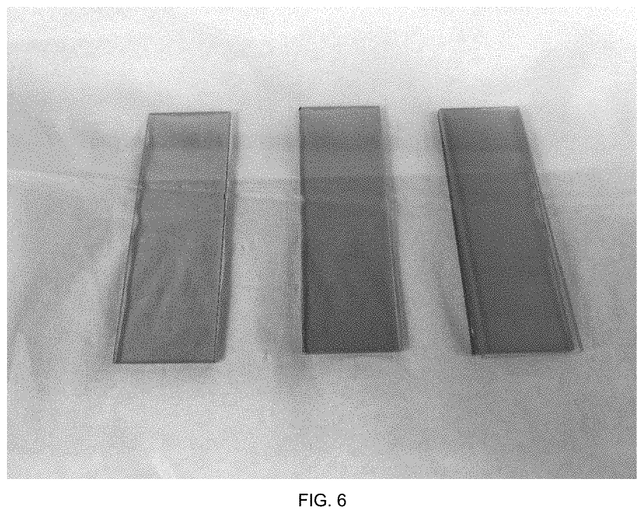

FIG. 7 is a schematic illustration of a laminated glass LC in combination with an insulated glass unit, a window frame and integrated photovoltaic devices.

FIG. 8 is a schematic illustration of a laminated glass LC in combination with an automobile.

FIG. 9 is a schematic illustration of a laminated glass LC in combination with a building structure.

### SUMMARY OF THE DISCLOSURE

In one aspect, a luminescent concentrator is provided, comprising (a) a waveguide; (b) a collection surface which directs radiation impingent upon it into said waveguide; (c) an emission surface which is smaller than said collection surface and which extracts radiation from said waveguide, wherein said waveguide guides radiation to said emission surface and concentrates the radiation as it does so; (d) a first light-absorbing species having a first absorption spectrum, wherein said first light-absorbing species is a fluorophore, and wherein said first absorption spectrum has a visible region with at least one absorption band therein; and (e) at least one element selected from the group consisting of (i) a second light-absorbing species having a second absorption spectrum, wherein said second absorption spectrum has a visible region with at least one absorption band therein, and (ii) a reflective layer having a transmission spectrum, wherein said transmission spectrum has a visible region with at least one transmission band therein; wherein at least one element increases the light absorption of the luminescent concentrator over at least a portion of the visible region of the electromagnetic spectrum.

In another aspect, a window is provided which comprises (a) first and second sheets of glass; (b) a polymeric medium disposed between said first and second sheets of glass; (c) first and second light absorbing species, wherein said first light absorbing species is disposed in said polymeric medium, and wherein said first and second light absorbing species absorb visible electromagnetic radiation and transmits near-infrared electromagnetic radiation. The device has a color neutral or grey appearance.

In some embodiments, the waveguide is coupled to a photovoltaic device; wherein said waveguide concentrates electromagnetic radiation on the photovoltaic device, and wherein the photovoltaic device converts the concentrated electromagnetic radiation into electricity.

In still another aspect, and in combination with a photovoltaic device, the LC has the ability to convert light, for example sunlight, into electricity. The result is a color-modified window that generates electricity.

### DETAILED DESCRIPTION

### 1. Background

The aesthetic features of windows are important in order for them to be not only acceptable façade materials, but desirable ones. Color is an especially important aesthetic feature for windows. In order to be competitive in the marketplace, solar windows should provide the same aesthetic features that consumers have come to associate with conventional windows.

Unfortunately, many of the solar windows developed to date are characterized by undesirable color tinting, which thus causes the color of such solar windows to deviate from the neutral ‘grey’ preferred in many window applications. In addition, some applications may require other colors that cannot be achieved with a single fluorophore. This issue arises because the semiconductor or dye absorbers commonly utilized in these devices typically have wavelength-varying absorption spectra. This issue is especially problematic for LCs, and is sometimes worsened by the occurrence of visible luminescence.

It has now been found that these issues may be overcome by embodiments of the compositions, structures, systems, methodologies and devices disclosed herein. Preferred embodiments of these compositions, structures, systems, methodologies and devices utilize an LC comprising a first light absorbing species (which is preferably a suitable fluorophore) embedded in a polymer matrix. The first light-absorbing species is preferably a plurality of quantum dots (QDs) having a large intrinsic Stokes shift such as, for example, those consisting of CuInSeₓS₂₋ₓ/ZnS (core/shell). When combined with an optically coupled photovoltaic device, the LC may generate electricity under illumination by sunlight or other radiation sources. A second light absorbing and/or light emitting species is also provided which modifies the transmission spectrum of the device so as to impart a neutral grey color to the device. In some embodiments, the second species is a radiation absorbing species which modifies the transmission spectrum of the device by selectively absorbing a portion of that spectrum (for example, by having an absorption peak greater than 520 nm), thus imparting a neutral grey color to the device. In still other embodiments, the second species may be a fluorophore, and thus may be both a radiation emitting species and a radiation absorbing species.

In some embodiments, the LC may be partially transparent, and may be used as (or in) a window of a building or vehicle. In such applications, additional benefits may be realized in the safety of building or automobile occupants, since the (preferably laminated) glass utilized in the foregoing constructs may be resistant to shattering. In certain embodiments and applications, the LC may be fully absorptive, and may therefore provide a lower-cost alternative to large area photovoltaics (such as, for example, those used in solar farms).

In some embodiments, semi-transparent LCs are provided that filter visible light neutrally so as to avoid imparting unnatural color to the light transmitted by the LC. In contrast to some conventional solar harvesting windows which utilize photovoltaic stacks that cover the entire window, preferred embodiments of the LCs disclosed herein typically require only a very narrow strip of photovoltaic (PV) material along one or more edges of the window. Conventional solar harvesting window concepts are hence intrinsically more expensive and complex than LCs, because they typically require coating an entire window with a complex, multi-layered PV material.

LCs may have advantages in applications beyond sunlight harvesting such as, for example, their use in lighting, design, security, art, and other applications where creating a new spectrum and/or higher photon flux is desirable. The same fluorophores and/or device geometries that are applicable to sunlight harvesting may be applicable to these other usages. In other cases, new fluorophores and/or new device geometries may be desirable for non-solar applications.

The fluorophores utilized in preferred embodiments of the systems, devices, structures and methodologies disclosed herein are characterized by photoluminescence (PL), which is the emission of light (in the form of electromagnetic radiation or photons) after the absorption of light. It is one form of luminescence (light emission), and is initiated by photoexcitation (the excitation by photons). Following photon excitation, various charge relaxation processes can occur in which other photons with a lower energy are re-radiated on some time scale. The energy difference between the absorbed photons and the emitted photons, also known as Stokes shift, can vary widely across materials from nearly zero to 1 eV or more.

Many conventional LC devices utilize monolithic polymer slabs embedded with common fluorophores (such as dyes or QDs). In some cases, these LCs have utilized one or more sheets of glass in their designs.

The production of LCs with commercially acceptable performance typically requires (a) highly smooth and robust outer surfaces, and (b) a bright fluorophore with low self-absorbance. In addition, low cost materials and methods, as well as low-toxicity materials, are key enablers of LC technology in most applications, solar or otherwise.

Colloidal semiconductor nanocrystals, also known as QDs, are vanishingly small pieces of semiconductor material that are typically less than 20 nm in diameter. As a result of their small size, these materials have several advantageous properties that include size-tunable PL emission over a wide-range of colors, a strong and broadband absorption, and a remarkably high PL efficiency. The solution processing techniques used to synthesize these materials allows the size of the QDs to be readily modified. The ability to tune QD size, and hence the associated absorption/emission spectra, allows flexible fluorescence to be attained across the full color spectrum with these materials, without the need to modify the composition of the QDs themselves.

As QD sizes increase, their absorption onset and PL spectra shift to longer wavelengths. Conversely, as QD sizes decrease, their absorption onset and PL spectra shift towards shorter wavelengths. The size tunability of colloidal QDs may be beneficial for LCs, since different colored QDs may be attractive for different applications or different settings. However, most QDs suffer from a large overlap between their absorption and emission spectra, resulting in significant self-absorption of their PL.

At present, the best performing QDs consist of CuInSeₓS₂₋ₓ (CISeS), which have the potential to be disruptive in the emerging QD industry due to their lower manufacturing costs, lower toxicity, and (in some cases) better performance. CuInS₂ (where x=0 in the above formula) outperforms the conventional QD material, CdSe, on such critical metrics as toxicity and cost. On performance metrics, CuInS₂ QDs (also referred to as CIS QDs) are favorable as well. For example, CIS QDs have stronger absorption than CdSe QDs. CIS QDs also have a large intrinsic Stokes shift (about 450 meV), which limits self-absorption in the material.

Nanocrystal QDs of the class of semiconductors, such as CIS QDs, are of growing interest for applications in optoelectronic devices such as solar photovoltaics (see, e.g., PVs, Stolle, C. J.; Harvey, T. B.; Korgel, B. A. Curr. Opin. Chem. Eng. 2013, 2, 160) and light-emitting diodes (see, e.g., Tan, Z.; Zhang, Y.; Xie, C.; Su, H.; Liu, J.; Zhang, C.; Dellas, N.; Mohney, S. E.; Wang, Y.; Wang, J.; Xu, J. Advanced Materials 2011, 23, 3553). These QDs exhibit strong optical absorption and stable efficient PL that can be tuned from the visible to the near-infrared (see, e.g., Zhong, H.; Bai, Z.; Zou, B. J. Phys. Chem. Lett. 2012, 3, 3167) through composition and quantum size effects. In fact, LCs made with specifically engineered QDs have recently been shown to offer excellent stability and record conversion efficiency (see Meinardi, F.; McDaniel, H.; Carulli, F.; Colombo, A.; Velizhanin, K. A.; Makarov, N. S.; Simonutti, R.; Klimov, V. I.; Brovelli, S., Highly efficient large-area colourless luminescent solar concentrators using heavy-metal-free QDs, Nature Nano., 10, 878, 2015). Indeed, it was shown by Meinardi et al. that the perception of color through CISeS LCs was not significantly perturbed when compared with colored dyes. However, those CISeS QD-only LCs tend to enhance the warmer colors, thus giving rise to an overall brown visual appearance. It has been noted by several architects that the typical brown color of CISeS LCs is reminiscent of an architectural style popular in the 1980's, while materials having a truer grey appearance would be more in conformance with current industry norms.

### 2. Definitions and Abbreviations

The following explanations of terms and abbreviations are provided to better describe the present disclosure and to guide those of ordinary skill in the art in the practice of the compositions, systems, methodologies and devices described therein.

Grey-colored: Grey in appearance. Grey means approximately color neutral by eye, somewhere between clear (no tint) and black (full tint). Because color can be perceived differently, the scope of the term includes blue-grey, green-grey, or brown-grey, or other slightly colored versions of ‘grey’.

Luminescent concentrator (LC): A device for converting a spectrum and photon flux of electromagnetic radiation into a new, and typically (but not always) narrower spectrum with a higher photon flux. LCs operate on the principle of collecting radiation over a large area by absorption, converting it to a new spectrum by PL, and then directing the generated radiation into a relatively small output target by total internal reflection. LCs are typically used for conversion of sunlight into electricity, but may also be used in lighting, design, and optical elements.

Photoluminescence (PL): The emission of light (electromagnetic radiation, photons) after the absorption of light. It is one form of luminescence (light emission) and is initiated by photoexcitation (excitation by photons).

Photon flux: The number of photons passing through a unit of area per unit of time, typically measured as counts per second per square meter.

Polymer: A large molecule, or macromolecule, composed of many repeated subunits. Polymers range from familiar synthetic plastics such as polystyrene or poly(methyl methacrylate) (PMMA), to natural biopolymers such as DNA and proteins that are fundamental to biological structure and function. Polymers (both natural and synthetic) are created via polymerization of many small molecules, known as monomers. Exemplary polymers include poly(methyl methacrylate) (PMMA), polystyrene, polycarbonate, silicones, epoxy resins, ionoplast, acrylates, vinyl, and nail polish.

Self-absorption: The percentage of emitted light from a plurality of fluorophores that is absorbed by the same plurality of fluorophores.

Toxic: Denotes a material that can damage living organisms due to the presence of phosphorus or heavy metals such as cadmium, lead, or mercury.

Quantum Dot (QD): A nanoscale particle that exhibits size-dependent electronic and optical properties due to quantum confinement. The QDs disclosed herein preferably have at least one dimension less than about 50 nanometers. The disclosed QDs may be colloidal QDs, i.e., QDs that may remain in suspension when dispersed in a liquid medium. Some of the QDs which may be utilized in the compositions, systems, methodologies and devices described herein may be made from a binary semiconductor material having a formula MaXb, where M is a metal, X typically is selected from sulfur, selenium, tellurium, nitrogen, phosphorus, arsenic, antimony or mixtures thereof, and a and b are real numbers (and frequently integers). Exemplary binary QDs which may be utilized in the compositions, systems, methodologies and devices described herein include CdS, CdSe, CdTe, PbS, PbSe, PbTe, ZnS, ZnSe, ZnTe, InP, InAs, Cu₂S, and In₂S₃. Other QDs which may be utilized in the compositions, systems, methodologies and devices described herein are ternary, quaternary, and/or alloyed QDs including, but not limited to, ZnSSe, ZnSeTe, ZnSTe, CdSSe, CdSeTe, HgSSe, HgSeTe, HgSTe, ZnCdS, ZnCdSe, ZnCdTe, ZnHgS, ZnHgSe, ZnHgTe, CdHgS, CdHgSe, CdHgTe, ZnCdSSe, ZnHgSSe, ZnCdSeTe, ZnHgSeTe, CdHgSSe, CdHgSeTe, CuInS₂, CuInSe₂, CuInGaSe₂, CuInZnS₂, CuZnSnSe₂, Culn(Se,S)₂, CuInZn(Se,S)₂, and AgIn(Se,S)₂ QDs, although the use of non-toxic QDs is preferred. Embodiments of the disclosed QDs may be of a single material, or may comprise an inner core and an outer shell (e.g., a (preferably thin) outer shell/layer formed by any suitable method, such as cation exchange). The QDs may further include a plurality of ligands bound to the quantum dot surface.

Quantum Yield (QY): The ratio of the number of emitted photons to the number of absorbed photons for a fluorophore.

Fluorophore: a material which absorbs a first spectrum of light and emits a second spectrum of light. A material that exhibits luminescence or fluorescence.

Stokes shift: the difference in energy between the positions of the absorption shoulder or local absorption maximum and the maximum of the emission spectrum.

Emission spectrum: Those portions of the electromagnetic spectrum over which a fluorophore exhibits PL (in response to excitation by a light source) whose amplitude is at least 1% of the peak PL emission.

### 3. Exemplary Embodiment

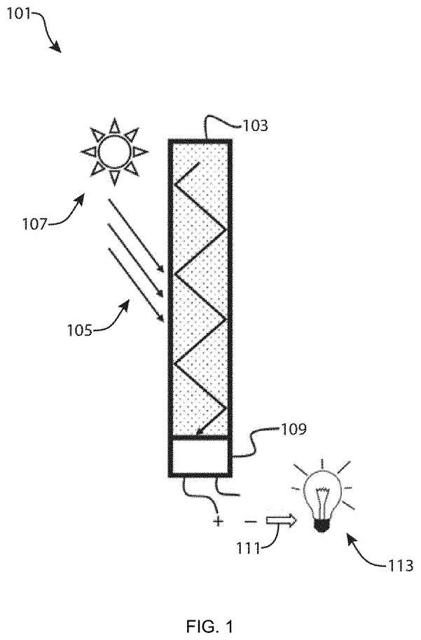

FIG. 1 depicts a first particular, non-limiting embodiment of a system in accordance with the teachings herein. As seen therein, the system 101 includes a LC 103 which collects radiation 105 from a radiation source 107. In the particular embodiment depicted, the radiation source 107 is the sun, and hence, the collected radiation 105 is solar radiation. The LC 103 is utilized to collect solar radiation 105 over a relatively large area, and to concentrate it onto a relatively small area (here, the active surface of a photovoltaic cell 109). The photovoltaic cell 109 then converts the radiation into electricity to provide power 111 for end user devices 113.

Notably, the LC 103 acts as a waveguide to funnel the collected radiation to the photovoltaic cell 109. The LC 103 comprises a luminescent material which both creates and transmits the same luminescence. Additionally, the LC 103 contains a suitable colorant at a suitable concentration to impart a more color-neutral, or grey, appearance to it. The waveguide typically comprises a polymeric material of optical quality. When sunlight or other radiation impinges on the luminescent material, the material undergoes luminescence (and most commonly, fluorescence) and emits light into the waveguide. From there, the entrapped light is directed to the photovoltaic cell 109. Since the radiation emitted by the luminescent material is typically emitted at different wavelengths than the radiation initially absorbed by the luminescent material, the LC 103 has the effect of both concentrating and modifying the spectrum of the radiation which is impingent on it.

In some variations of the embodiment of FIG. 1, the LC 103 contains a polymer that is extruded with fluorophores and a colorant. Suitable polymers for this embodiment may include, for example, polyvinyl butyral, EVA, urethane, or ionoplast. Suitable fluorophores may include, for example, CuInS₂/ZnS QDs. In some implementations, the extruded material may be sandwiched between two pieces of glass to complete the LC 103.

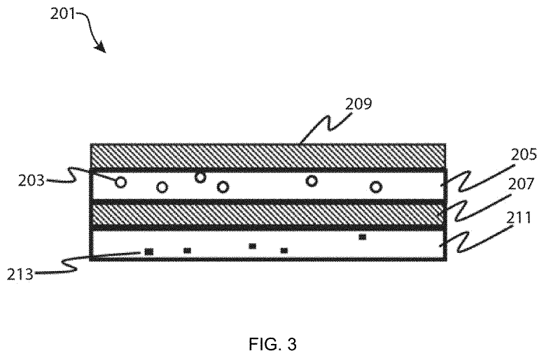

FIG. 3 depicts another particular, non-limiting embodiment of a product 201 in accordance with the teachings herein. The particular embodiment depicted therein includes QDs 203 embedded in a polymer matrix 205. In some embodiments, the adjacent intermediate layers 207 and 209, which may be the same or different, may comprise glass, polymeric materials, air, vacuum, or combinations thereof. A second layer 211 containing a colorant 213 is coated or adhered to one surface of a window.

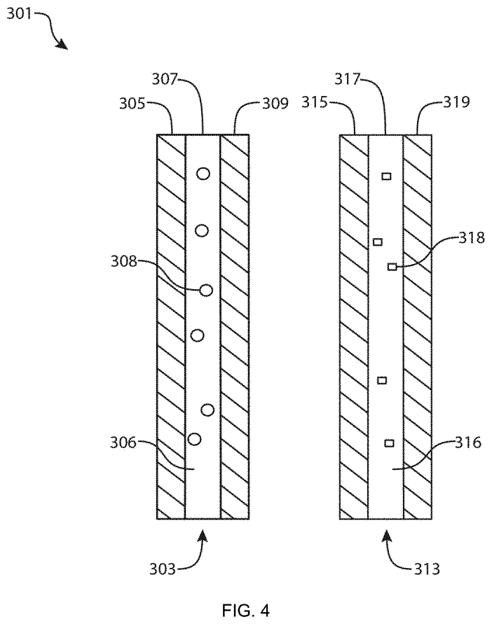

FIG. 4 depicts a further particular, non-limiting embodiment of a product 301 in accordance with the teachings herein. The particular embodiment 301 depicted therein includes first 303 and second 313 layer stacks. The first 303 layer stack includes layers 305, 307 and 309. Similarly, the second 313 layer stack includes layers 315, 317 and 319. Any of layers 305, 309, 315 and 319 may be the same or different and may comprise glasses, polymers, air, a vacuum, or combinations thereof. In some embodiments, layer 305 may be combined into a single layer with layer 315 or 319, or layer 309 may be combined into a single layer with layer with layers 315 or 319.

Layers 307 and 317 comprise a polymeric matrix which may be the same or different. Layer 307 contains a first continuous phase 306 and a first disperse phase 308, and layer 313 contains a second continuous phase 316 and a second (preferably disperse) phase 318. Any of layers 305, 309, 315 and 319 may be the same or different and may comprise glasses, polymers, air, a vacuum, or combinations thereof.

In a preferred species of the foregoing embodiment, the first disperse phase 308 comprises QDs, and the second (preferably disperse) phase 318 comprises a colorant. Such a species thus illustrates the use of QDs and a colorant in two separate polymer matrices that are part of the same window unit.

### EXAMPLES

The following examples are non-limiting, and are merely intended to further illustrate the compositions, systems, methodologies and devices disclosed herein.

### Example 1: Incorporating a Colorant into a QD-LC

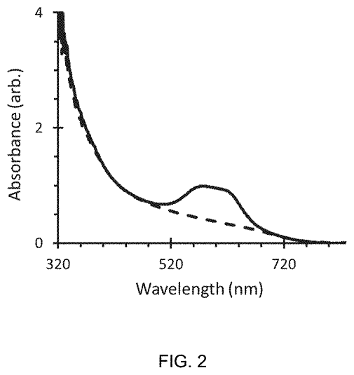

In one embodiment, reconciling the discrepancy between red and blue photon absorption was achieved by the introduction of a red-band absorbing, blue-appearing dye into the LC design. An optical transmission spectrum was obtained for a window of the type depicted in FIG. 1 which contained QDs and a non-fluorescent blue dye (Victoria Blue R, Millipore Sigma) colorant. The resulting spectrum is shown in FIG. 2. Spectrum 1 (dashed line) depicts the spectrum of a window containing QDs only, while spectrum 2 (solid line) depicts the window containing QDs and a blue colorant. Converting the spectra to CIELAB color coordinates under D50 illumination gives L=74.8, a=−6.8, b=−31.7 for windows with QDs only and L=93.4, a=7.7, b=−0.7 for windows containing QDs and blue colorant. A reduction in CIE b value, which quantifies color from blue (−) to yellow (+), indicates that color is effectively modified to be bluer by the introduction a red-band absorber. Since the dye optical properties are coupled to the waveguide, the absorption and/or scattering induced by the dye also affects the LC optical efficiency.

The visual light transmittance (VLT) of the LC may decrease using this method due to light scattering induced by the colorant and absorption of visible light by the colorant. The same blue dye molecule and QDs with peak emission of 830 nm were incorporated into an acrylic matrix. These samples had lower loadings of QDs than the sample represented by FIG. 2. As a result, the transmissive color of the QD window without added colorant under D50 illumination in CIELAB coordinates was L=44, a=−4, b=−17. With the dye, the CIELAB coordinates were L=50, a=0, b=−11. With the dye, the visual light transmittance (VLT) is 38%, which is about 12% lower than without the dye (VLT of 50% without the dye). These results were compared with a color-neutral tinted commercial glass (Sunguard High Performance Neutral 40% VLT, made by Guardian Glass). A CIE b value of −4.3 was measured for this commercially available ‘color-neutral’ glass, +21.8 for the unmodified QD-LC, and −14.7 for the dye-containing LC. With further optimization, a range of color neutral tints should be achievable.

If the dye is non-fluorescent, the QY of the system may be reduced by the dye. A QD-LC was prepared with QDs that emit at 830 nm and Victoria Blue R (Millipore Sigma) colorant was added. The Two samples were tested with constant QD concentration. One had a low colorant concentration while the other had a high colorant concentration. At the higher concentration of blue dye, the sample had a VLT of 38% and <1% haze. The effective QY for the full system was 42%. At the lower concentration of blue dye, the sample had a VLT of 49% and <1% haze. The effective QY for the full system was 57%. Without the dye, the QY for an LC sample with the same emission is above 70%, and in the optimal cases, above 80-90%. This QY reduction also resulted in the external optical quantum efficiency (the ratio of edge-emitted photons to incident excitation photons) of the QD+dye LC glass being reduced, when excited with blue light, by about 12% than the QD-LC without the dye.

In order to maintain constant visible light transmission (VLT) using this blue dye, the QD concentration used for LC interlayer needs to be reduced by roughly 50% in this case. The main drawback of this approach is a significant external optical quantum efficiency reduction of −81% (relative to the unmodified QD-LC), which is at least partially attributed to the lower QD concentration (−50%). Additionally, higher haze in the color-modified LC (0.7%) compared to the unmodified QD-LC (0.4%) could explain the excessive performance drop by way of added light scattering. The increased haze was likely due to new interactions between the dye, QDs, and other resin components, causing dye and/or QD aggregation.

### Example 2: Combining a QD-LC with a Colorant Coating

In another embodiment of the structures, devices, compositions and methodologies disclosed herein, a structure is provided which features the use of QDs and colorant in two separate polymer matrices that are part of the same window unit. In the structure 201, which is depicted in FIG. 3, QDs 203 are embedded in a polymer matrix 205. In some embodiments, the adjacent intermediate layers 207, 209 are glass, polymer, air, vacuum, or combinations thereof. A second film 211 containing colorant 213 is coated or adhered to one surface of the QD-LSC. The second film 211 may contain other technologies in addition to colorant. Alternatively, the QD polymer matrix could serve as a coating on the outer surface of the glass, and the colorant polymer matrix could serve as an interlayer or part of an interlayer in the glass laminate.

### Example 3: Combining QD-LC with a Separated Colorant Layer

In another embodiment of the structures, devices, compositions and methodologies disclosed herein, a structure is provided which comprises separate polymer matrices for the QDs and the colorant as described in FIG. 4. Since the colorant optical properties are coupled to the waveguide, the absorption and/or scattering induced by the dye also affect the LC optical efficiency. Light scattering reduces optical performance of the LC. In the structure 301 depicted therein, the QDs 308 are incorporated into a polymer matrix 306 that is used as an interlayer or coating on a glass substrate 305, 309. The colorant 318 is incorporated into a polymer matrix 316 that is used as an interlayer or coating on a separate glass substrate 315, 319. The two stacks of material are used in an integrated glass unit where the QD polymer matrix and colorant polymer matrix are optically decoupled. In this configuration, the transmissive color of the QD window alone under D50 illumination in CIELAB coordinates was L=44, a=−4, b=−17. With the blue colorant-coated laminated glass in front of the QD laminated glass, the CIELAB coordinates were L=50, a=0, b=−10. VLT dropped by 10% with the addition of the blue laminated glass, but the external optical efficiency under blue light illumination remained the same. These results were the same whether looking at the glass through the QD layer first or the dye layer first.

### Example 4: Combining QD-LC with a Colored Low-E Coating

In another embodiment of the structures, devices, compositions and methodologies disclosed herein, a structure is provided which comprises a QD LC combined with a low-emissivity (low-E) coating to impart a color neutral combined effect. Window glass is often highly transmissive in the infrared. To improve thermal control, thin film coatings are applied to the glass that are reflective in the infrared or near-infrared. There are several methods of creating a low-E coating, and the most common ways are with either a transparent conducting oxide such as indium-doped tin oxide, or alternating dielectric with metal coatings, commonly silver. Such specially designed coatings may be applied to one or more surfaces of insulated glass, and often impart a blue or green color to the resulting window. With the proper combination of QD-tinted glass and low-E coating, a grey, color-neutral widow may be obtained which exhibits enhanced thermal and optical properties. A typical low-e coating may have a maximum transmission in the infrared region of less than 0.65.

In order to test the effects of a reflective coating on performance, a completed QD-LC device was measured with a black background, and a power conversion efficiency (PCE) of 3.0% was observed. The same device was measured with a reflective background (mirror, with a maximum transmission in the infrared region of less than 0.2), and exhibited a PCE of 3.6%, or +20% (relative) more than when measured on the black background. Unlike the loss of performance due to the addition of a colorant (described in example 1), the use of a reflective coating, such as a low-e coating, should boost optical efficiency by achieving color modification with reflection rather than absorption.

### Example 5: Combination with Vehicles and Structures

Glass windows with luminescent tints may enable building-integrated sunlight harvesting and revolutionize urban architecture by turning tinted windows into power sources. With this technology, buildings may eventually realize net zero energy consumption, automated greenhouses may be off-grid, and electric vehicles may charge themselves while sitting parked. As noted above, in a preferred embodiment, the luminescent concentrators disclosed herein are equipped with first and second sheets of glass that have a solid medium containing a plurality of fluorophores disposed between them. Such devices disclosed herein may be used as passive electrical energy supplies on a building or vehicle.

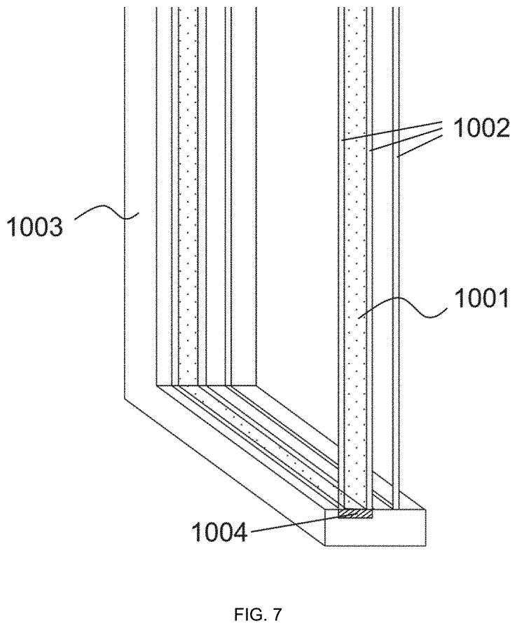

FIG. 7 depicts a particular, non-limiting embodiment in which laminated glass LC 1001 is integrated into an insulated glass unit (IGU) 1002, commonly referred to as a double pane window with three sheets of glass. In some embodiments, the IGU may be a triple pane window including a fourth sheet of glass. In some embodiments, the LC-integrated IGU 1002 may be combined with a window frame 1003. The LC 1001 need not be part of an IGU to be combined with a window frame 1003, and this is commonly referred to as a single pane window. A plurality of solar cells 1004 are integrated into the window frame 1003 or the IGU 1002 (or some combination of both) and are optically coupled to the LC 1001 for generation of electricity (see FIG. 1).

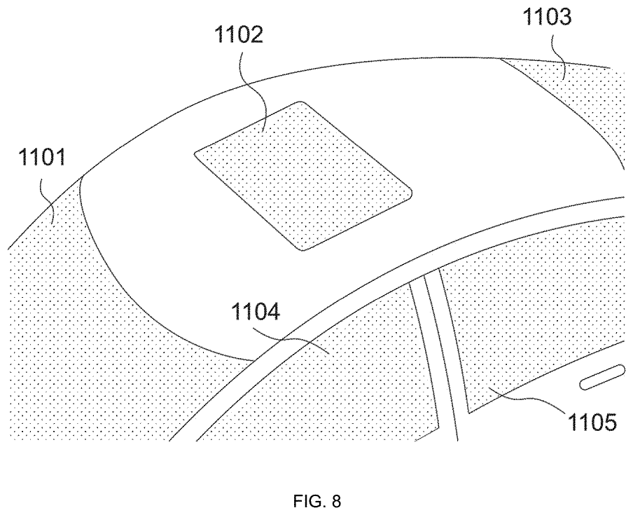

FIG. 8 is a representative schematic of a particular, non-limiting embodiment of an automobile combined with one or more laminated glass LC windows. The LC can be applied as or integrated into the front windshield 1101, sunroof 1102, rear window 1103, front side window 1104, rear side window 1105, or combinations thereof. Preferably, the LC technology would be combined with an electric vehicle, but gas mileage may be improved for non-electric or hybrid vehicles. In some embodiments, the LC may be used to power electrical devices or components (such as a fan) while the vehicle remains parked. In some embodiments, the vehicle is not a car, and may be, for example, a boat, truck, military vehicle, heavy equipment, airplane, helicopter, space vehicle, satellite, or other vehicle.

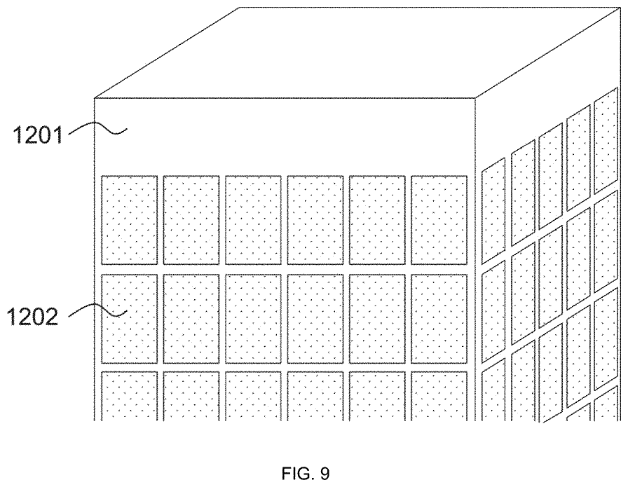

FIG. 9 is a representative schematic of a particular, non-limiting embodiment of a building structure 1201 equipped with one or more laminated glass LC windows 1202. The LC windows 1202 may be applied on one or more sides of the building 1201, or on one or more floors of the building 1202. In some embodiments, the LC windows may be flat or rectangular. In other embodiments, the LC windows may be curved or have arbitrary shapes. In some embodiments, the building structure may contain commercial space, residential space, retail space, or combinations thereof. In some embodiments, the building may be a greenhouse, airport, skyscraper, lunar habitat, non-earth habitat, an undersea habitat, a covert military structure, or other type of building.

### Example 6: Combining QD-LC with Multiple Laminated Interlayers

In another embodiment of the structures, devices, compositions and methodologies disclosed herein, a structure is provided which comprises a QD LC combined with multiple laminated interlayers, where each laminated interlayer contains the same concentration of QDs. LC windows designed with darker tints may benefit from improved performance owing to higher absorption. In an attempt to achieve lower VLT, a single-interlayer QD-LC with 6 wt % QD loading was fabricated. This exemplary device has a VLT of 11.1%; however, the haze is visibly apparent and measured at 2.4%, presumably owing to QD aggregation. In addition to being a loss mechanism leading to underperformance, high haze negatively affects window aesthetics by giving the interlayer a visibly cloudy appearance. To achieve high LC absorption without adding significant haze, QD loading was reduced to 1.7 wt % and LCs of up to five identical interlayers were constructed. The result is a similar VLT of 13.7%, but with a much lower haze of 0.9%.

Multi-interlayered LCs with area of 15.24 cm×15.24 cm were built up one layer at a time according to a cast-in-place method. Sample properties such as optical efficiency, VLT, haze, and solar absorption were measured in progressive order, before the addition of each successive interlayer. As expected, VLT decreases and solar absorption increases as the number of LC interlayers is increased. No saturation in solar absorption is observed, even at five interlayers. The external optical quantum efficiency averaged across the solar spectrum also increases with the number of interlayers. However, this increase is not linear with solar absorption. While solar absorption doubles going from a one- to five-interlayers, external optical quantum efficiency averaged across the solar spectrum only increases by ˜30%. Internal optical quantum efficiency, defined as external optical quantum efficiency divided by absorption, represents the effectiveness of an LC in converting absorbed light into edge-delivered photoluminescence and can provide information about device performance versus sunlight absorption. Although the internal optical quantum efficiency averaged across the solar spectrum decreases with the number of interlayers, there is still a benefit for the external optical quantum efficiency averaged across the solar spectrum due to increased solar absorption.

In order to characterize the benefits in electrical performance of the LC architectures with the best optical properties, two- and three-interlayer devices were completed by coupling monocrystalline Si solar cells (IXYS Corporation) to the LCs' perimeter. A total of 28 solar cells (7 cells per edge) were attached per device and the cells were wired in series for both samples. The VLT values of the new two- and three-interlayer devices are 39% and 25%, and corresponding haze values are 0.4% and 0.5%, respectively. The two completed samples were then sent for PCE certification at the National Renewable Energy Laboratory (NREL). Devices were certified over an absorbing black background and a reflective mirror background to characterize performance in the absence and presence of reflections that would afford secondary-pass light absorption.

The current-voltage (I-V) curves for the two- and three-interlayer devices were measured over a black background, and the I-V curve of the three-interlayer device was measured over a reflective background. With a black background, the three-interlayer device exhibits the highest PCE of 3.0%, while the two-interlayer device exhibits a PCE of 2.8%. The PCE of the three-interlayer LC with the reflective background exhibits a certified PCE of 3.6%, or +22% (relative) more than when measured on the black background. Measurements of normalized electrical quantum efficiency (QE, also known as incident photon-to-electron conversion efficiency) of the devices shows increasing photocurrent in the 500-700 nm spectral range across these three test cases, suggesting that the increase in efficiency is related to enhanced absorption of light.

To equitably compare partially-transparent PV technologies with different absorptive properties, PCE values can be normalized by dividing by the solar absorption. The normalized PCE of the two- and three-interlayer LCs measured on a black background were calculated to be 5.89% and 5.17%, respectively. These results show that even though the overall PCE is higher for the three-interlayer sample, the double interlayer device converts absorbed photons to electrical power more efficiently.

### Example 7: Combining QD-LC with Multiple Laminated Interlayers with Different Composition in Different Interlayers

In another embodiment of the structures, devices, compositions and methodologies disclosed herein, a structure is provided which comprises a QD LC combined with multiple laminated interlayers, where the laminated interlayers may incorporate different colorants or QDs. In this way, an added colorant may modify the appearance of the window but may be physically separated from the QD interlayer so as to reduce parasitic light absorption. The benefit of this approach is that it enables creation of a more optimal host matrix environment for the colorant, which differs from the optimal host matrix environment for the QDs. This is an effective strategy for reducing haze in a multilayer LC device, and therefore enhancing optical efficiency by reducing light scattering.

### 5. Additional Comments

Various modifications, substitutions, combinations, and ranges of parameters may be made or utilized in the compositions, devices and methodologies described herein without departing from the scope of the present disclosure.

As used herein, “comprising” means “including” and the singular forms “a” or “an” or “the” include plural references unless the context clearly indicates otherwise. The term “or” refers to a single element of stated alternative elements or a combination of two or more elements, unless the context clearly indicates otherwise.

Unless explained otherwise, all technical and scientific terms used herein have the same meaning as commonly understood to one of ordinary skill in the art to which this disclosure relates. Suitable methods and compositions are described herein for the practice or testing of the compositions, systems, methodologies and devices described herein. However, it is to be understood that other methods and materials similar or equivalent to those described herein may be used in the practice or testing of these compositions, systems, methodologies and devices. Consequently, the compositions, systems, methodologies, devices and examples disclosed herein are illustrative only, and are not intended to be limiting. Other features of the disclosure will be apparent to those skilled in the art from the following detailed description and the appended claims.

Unless otherwise indicated, and with respect to all numbers expressing quantities of components, percentages, temperatures, times, and so forth, the scope of the present disclosure includes all instances of such numbers as if modified by the term “about.” Similarly, unless otherwise indicated, and with respect to all non-numerical properties such as colloidal, continuous, crystalline, and so forth, the scope of the present disclosure includes all instances of such non-numerical properties as if modified by the term “substantially”, which term shall mean “to a great extent or degree”. Moreover, unless otherwise indicated implicitly or explicitly, the numerical parameters and/or non-numerical properties set forth are approximations that may depend on the desired properties sought, the limits of detection under standard test conditions or methods, the limitations of the processing methods, and/or the nature of the parameter or property. When directly and explicitly distinguishing embodiments from discussed prior art, the embodiment numbers are not approximations unless the word “about” is recited.

What is claimed is:

1. A luminescent concentrator, comprising:
a waveguide;
a collection surface which directs radiation impingent upon it into said waveguide;
an emission surface which is smaller than said collection surface and which extracts radiation from said waveguide, wherein said waveguide guides radiation to said emission surface and concentrates the radiation as it does so;
a first light-absorbing species having a first absorption spectrum, wherein said first light-absorbing species is a fluorophore, and wherein said first absorption spectrum has a visible region with at least one absorption band therein; and
at least one element selected from the group consisting of
(a) a second light-absorbing species having a second absorption spectrum, wherein said second absorption spectrum has a visible region with at least one absorption band therein, and
(b) a reflective layer having a transmission spectrum, wherein said transmission spectrum has a visible region with at least one transmission band therein;
wherein said at least one element increases the light absorption of the luminescent concentrator over at least a portion of the visible region of the electromagnetic spectrum.

2. The luminescent concentrator of claim 1 in combination with a photovoltaic device, wherein said luminescent concentrator outputs concentrated radiation, and wherein said photovoltaic device converts said concentrated radiation into electricity.

3. The luminescent concentrator of claim 1, wherein said first light-absorbing species is a plurality of quantum dots.

4. The luminescent concentrator of claim 1, wherein said at least one element includes said second light-absorbing species, wherein said first light-absorbing species has stronger absorption in a blue region of the spectrum than a red region of the spectrum, and wherein said second light-absorbing species has stronger absorption in the red region of the spectrum than the blue region of the spectrum.

5. The luminescent concentrator of claim 1, wherein said fluorophore is a plurality of quantum dots comprising a material selected from the group consisting of CuInS₂, CuInSe₂, ZnS, ZnSe, and alloys of the same.

6. The luminescent concentrator of claim 1, wherein said waveguide comprises a medium, and wherein said medium comprises a material selected from the group consisting of ethylene-vinyl acetate, polyvinyl butyral, thermoplastic polyurethane, poly(methyl methacrylate), poly (lauryl methacrylate), acrylate polymer, urethanes, vinyl polymer, cellulose, ionomer, ionoplast, cyclic olefin polymer, polycarbonate, epoxies, and silicone.

7. The luminescent concentrator of claim 6, wherein said medium is an extruded article.

8. The luminescent concentrator of claim 6, wherein said at least one element is a second light-absorbing species, and wherein said first and second light-absorbing species are embedded in said polymeric medium.

9. The luminescent concentrator of claim 1, further comprising a medium and first and second sheets of glass, and wherein said medium contacts said first and second sheets of glass across first and second non-reflective interfaces.

10. The luminescent concentrator of claim 1, wherein said fluorophore has a quantum yield of at least 50%.

11. The luminescent concentrator of claim 1, wherein said fluorophore has an emission peak between 400 nm and 1300 nm.

12. The luminescent concentrator of claim 1, wherein said fluorophore has a self-absorption of less than 50% of its photoluminescence across the integrated spectrum over distances of at least 1 cm.

13. The luminescent concentrator of claim 1, wherein said fluorophore has a Stokes shift of greater than 100 meV.

14. The window unit of claim 1, wherein the said at least one element is spaced apart from the luminescent concentrator by way of an air gap.

15. A window unit comprising the luminescent concentrator of claim 1, wherein the said at least one element is disposed on a surface of said luminescent concentrator.

16. The window unit of claim 15, wherein said window unit comprises at least one sheet of glass, and wherein a coating is disposed on said at least one sheet of glass.

17. The window unit of claim 16, wherein said coating has a reflection band or an absorption band in a blue region of the spectrum.

18. The window unit of claim 16, wherein said coating is a low-E coating.

19. The window unit of claim 18, wherein the said at least one element has a maximum transmission in the infrared region of less than 0.65.

20. The window unit of claim 1, wherein the at least one element is blue.
